(19) United States
(12) Patent Application Publication
(10) Pub. No.: US 2008/0003819 A1
(43) Pub. Date: Jan. 3, 2008

(54) Laser isolation of metal over alumina underlayer and structures formed thereby

(75) Inventors: Morgan T. Johnson, Portland, OR (US); James E. Fitzgerald, Hillsboro, OR (US)

Correspondence Address: RAYMOND J. WERNER, 2056 NW ALOCLEK DRIVE, SUITE 314, HILLSBORO, OR, 97124, US

(73) Assignee: Octavian Scientific, Inc.

(21) Appl. No.: 11/811,880

(22) Filed: Jun. 11, 2007

Related U.S. Application Data
(60) Provisional application No. 60/812,152, filed on Jun. 9, 2006.

(51) Int. Cl. H01L 21/44

(52) U.S. Cl. 438/669; 257/E21.476

(57) ABSTRACT

A method of reducing or eliminating electrical shorts in a metal layer when producing laser patterned metal disposed on an intermediate layer that is disposed on a substrate, such as for example, a silicon wafer, includes forming the intermediate layer from a material wherein the difference between the coefficient of thermal expansion of the intermediate layer and the coefficient of thermal expansion of the metal is less than the difference between the coefficient of thermal expansion of silicon dioxide and the coefficient of thermal expansion of aluminum. In one embodiment, a layer of alumina is deposited on a silicon wafer, a layer of aluminum is deposited on the alumina, and at least portions of the aluminum are removed by laser etching to produce one or more electrically separated structures from the aluminum layer.

### CROSS-REFERENCE TO RELATED APPLICATIONS

This non-provisional application claims the benefit of provisional application 60/812,152, filed 09 Jun. 2006, and entitled “Laser Isolation Of Metal Over Alumina Underlayer And Structures Formed Thereby”, the entirety of which is hereby incorporated by reference.

### FIELD OF THE INVENTION

The present invention relates generally to methods for making electrically isolated conductive regions by laser etching a conductive material disposed over and separated from a silicon based substrate by a first layer of material.

### BACKGROUND

The use of industrial laser systems in a wide variety of tasks has grown dramatically in the past few decades. In particular, the use of such laser systems to pattern, or etch, metal layers on various substrates is well-known. Such uses include, for example, blowing fuse links on semiconductor devices for the purpose of replacing various defective circuit blocks with properly functioning circuit blocks. This type of laser fuse programming for redundancy has been used for a number of years.

Laser etching of metal layers on printed circuit boards, and on mask plates used in semiconductor manufacturing has also been known for a number of years.

Certain applications of laser based metal removal, i.e., laser etching of metal layers, have been found to be problematic. For example, laser etching of aluminum disposed on an oxide of silicon (e.g., SiO₂) disposed on a silicon wafer, has been found to produce poor results because of the large number of electrical shorts between the separate structures that are desired to be produced by laser etching.

What is needed are methods for making electrically isolated conductive regions by laser etching while reducing or eliminating the electrical shorts that are typically formed by such a process.

### SUMMARY OF THE INVENTION

Briefly, a method of reducing, or eliminating, electrical shorts in a metal layer when producing laser patterned metal disposed on an intermediate layer that is disposed on a substrate, such as for example, a silicon wafer, includes forming the intermediate layer from a material wherein the difference between the coefficient of thermal expansion of the intermediate layer and the coefficient of thermal expansion of the metal is less than the difference between the coefficient of thermal expansion of silicon dioxide and the coefficient of thermal expansion of aluminum. In one embodiment, a layer of alumina is deposited on a silicon wafer, a layer of aluminum is deposited on the alumina, and at least portions of the aluminum are removed by laser etching to produce one or more electrically separated structures from the aluminum layer.

In one aspect of the present invention, the alumina layer is sputtered onto the surface of the silicon wafer.

In a further aspect of the present invention, substrates other than silicon wafers, for example, silicon carbide wafers, may be used.

### BRIEF DESCRIPTION OF THE DRAWINGS

FIG. 1 is a flow diagram of a process of forming electrically isolated structures by laser etching in accordance with the present invention.

FIG. 2 is a flow diagram of a process of forming electrically isolated metal structures over a layer of alumina by laser etching in accordance with the present invention.

FIG. 3 is a cross-sectional view of a patterned aluminum disposed over a layer of alumina, which is disposed on a silicon wafer.

### DETAILED DESCRIPTION

Various embodiments of the present invention provide a method of patterning, by means of laser etching, a metal layer disposed on a first material layer which is disposed on a semiconductor substrate. Previous attempts in industry to laser etch aluminum disposed on silicon dioxide over a silicon substrate have been impractical because electrical shorting has resulted from these processes, thereby preventing the reliable formation of electrically isolated conductive structures by laser etching.

In typical embodiments of the present invention, an aluminized silicon wafer, with the aluminum deposited on a layer of aluminum oxide, or alumina, is patterned by a laser.

Reference herein to “one embodiment”, “an embodiment”, or similar formulations, means that a particular feature, structure, operation, or characteristic described in connection with the embodiment, is included in at least one embodiment of the present invention. Thus, the appearances of such phrases or formulations herein are not necessarily all referring to the same embodiment. Furthermore, various particular features, structures, operations, or characteristics may be combined in any suitable manner in one or more embodiments.

Terminology

The term “pad”, as used herein, generally refers to a conductive region where physical and electrical connection between one component and another is made. In the context of integrated circuits, pad typically refers to a metallized region of the surface of the integrated circuit, which is commonly used to form a physical connection terminal for communicating signals to and/or from the integrated circuit. Such integrated circuit pads may be formed of a metal, a metal alloy, or a stack structure including several layers of metals and/or metal alloys that are present, typically, at the uppermost layer of conductive material of an integrated circuit.

The expression “wafer translator” refers to an apparatus facilitating the connection of pads (sometimes referred to as terminals, I/O pads, contact pads, bond pads, bonding pads, chip pads, test pads, or similar formulations) of unsingulated integrated circuits, to other electrical components. It will be appreciated that “I/O pads” is a general term, and that the present invention is not limited with regard to whether a particular pad of an integrated circuit is part of an input, output, or input/output circuit. A wafer translator is typically disposed between a wafer and other electrical components, and/or electrical connection pathways. The wafer translator is typically removably attached to the wafer (alternatively the wafer is removably attached to the translator). The wafer translator includes a substrate having two major surfaces, each surface having terminals disposed thereon, and electrical pathways disposed through the substrate to provide for electrical continuity between at least one terminal on a first surface and at least one terminal on a second surface. The wafer-side of the wafer translator has a pattern of terminals that matches the layout of at least a portion of the pads of the integrated circuits on the wafer. The wafer translator, when disposed between a wafer and other electrical components such as an inquiry system interface, makes electrical contact with one or more pads of a plurality of integrated circuits on the wafer, providing an electrical pathway therethrough to the other electrical components. The wafer translator is a structure that is used to achieve electrical connection between one or more electrical terminals that have been fabricated at a first scale, or dimension, and a corresponding set of electrical terminals that have been fabricated at a second scale, or dimension. The wafer translator provides an electrical bridge between the smallest features in one technology (e.g., pins of a probe card) and the largest features in another technology (e.g., bonding pads of an integrated circuit). For convenience, wafer translator is referred to simply as translator where there is no ambiguity as to its intended meaning. In some embodiments a flexible wafer translator offers compliance to the surface of a wafer mounted on a rigid support, while in other embodiments, a wafer offers compliance to a rigid wafer translator. The surface of the translator that is configured to face the wafer in operation is referred to as the wafer-side of the translator. The surface of the translator that is configured to face away from the wafer is referred to as the inquiry-side of the translator. An alternative expression for inquiry-side is tester-side.

The expression “translated wafer” refers to a wafer that has a wafer translator attached thereto, wherein a predetermined portion of, or all of, the contact pads of the integrated circuits on the wafer are in electrical contact with corresponding electrical connection means disposed on the wafer side of the translator. Typically, the wafer translator is removably attached to the wafer. Removable attachment may be achieved by means of vacuum, or pressure differential, attachment.

The terms die, chip, integrated circuit, semiconductor device, and microelectronic device are sometimes used interchangeably in this field. The present invention relates to the fabrication of equipment for the manufacture and test of chips, integrated circuits, semiconductor devices and microelectronic devices as these terms are commonly understood in the field.

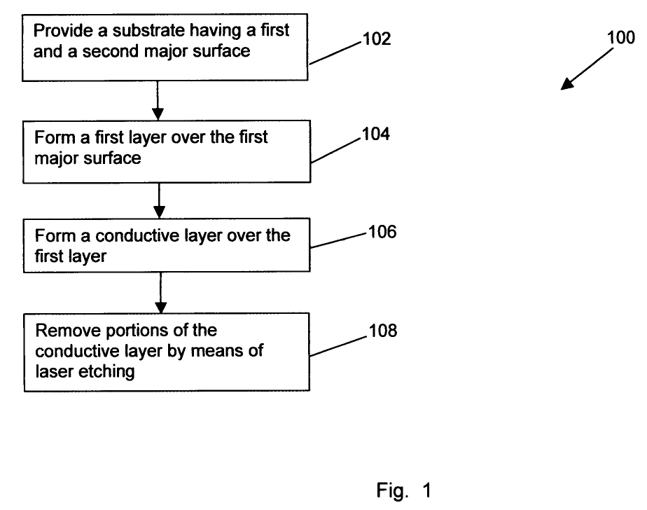

FIG. 1 is a flow diagram of a process 100 of forming isolated conductive structures on an intermediate layer disposed on a substrate in accordance with the present invention. More particularly, a substrate having a first major surface and a second major surface are provided 102, and an intermediate layer is formed 104 over the substrate. A conductive layer is then formed 106 over the intermediate layer. Portions of the conductive layer are then removed 108 by laser etching. In various embodiments of the present invention the intermediate layer comprises a material wherein the difference between the coefficient of thermal expansion of the intermediate layer and the coefficient of thermal expansion of the conductive layer is less than the difference between the coefficient of thermal expansion of silicon dioxide and the coefficient of thermal expansion of aluminum. In some embodiments of the present invention, the difference between the thermal conductivity of the intermediate layer and the thermal conductivity of the conductive layer is less than the difference between the thermal conductivity of silicon dioxide and the thermal conductivity of aluminum.

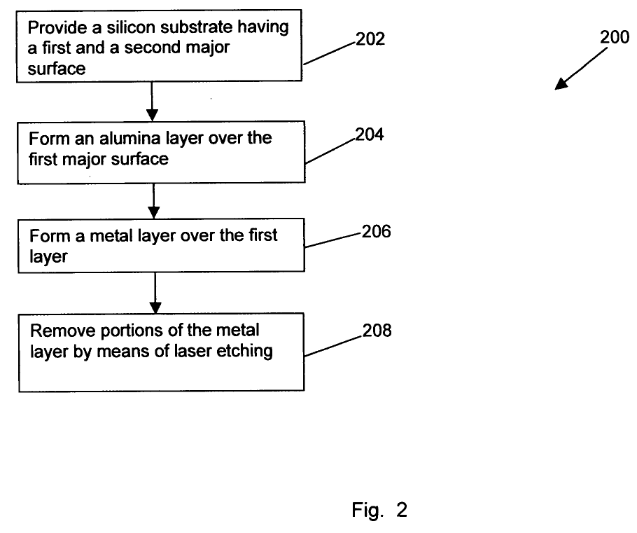

FIG. 2 is a flow diagram of a process 200 of forming isolated metal structures on an alumina layer disposed on a silicon substrate in accordance with the present invention. More particularly, a silicon substrate having a first and a second major surface is provided 202. Such a silicon substrate may be a silicon wafer of the types commonly used in semiconductor manufacturing. An alumina layer is formed 204 over the first major surface. The alumina layer may be formed by any suitable method, including, but not limited to, sputtering. A metal layer is formed 206 on the alumina layer. In some embodiments the metal layer comprises aluminum. Portions of the conductive layer are then removed 208 by laser etching. In some embodiments, the laser etching removes a portion of the metal layer down to the alumina layer while leaving substantially all of the alumina exposed by the removal of the overlying metal. In this way, the metal is separated into electrically isolated structures. In other embodiments, the laser etching removes a portion of the metal layer and a portion of the underlying alumina layer. In still other embodiments, the laser etching removes a portion of the metal layer and substantially all of the underlying alumina exposed by the removal of the overlying metal. In still other embodiments, the laser etching removes a portion of the metal layer, substantially all of the underlying alumina exposed by the removal of the overlying metal, and further removes a portion of the substrate exposed by the removal of the overlying metal and alumina. In still other embodiments, combinations of the depths of various openings formed by laser etching may be had.

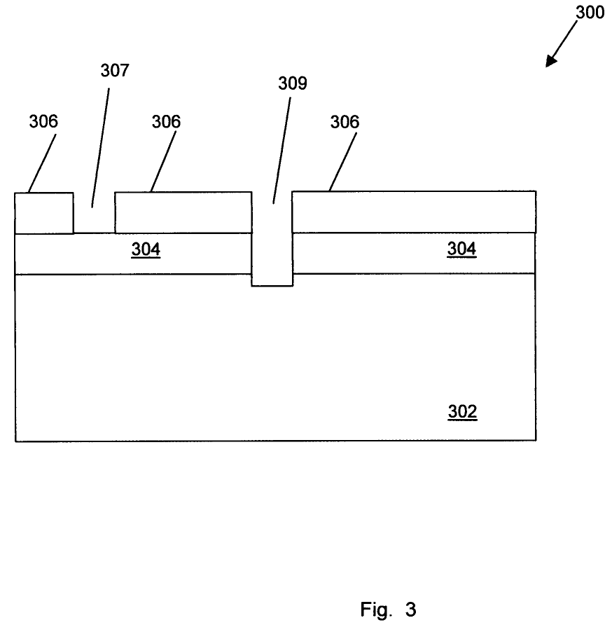

FIG. 3 is a cross-sectional view of a structure 300 in accordance with the present invention. FIG. 3 is illustrative and not necessarily drawn to scale. A silicon substrate 302 is provided with an alumina layer 304 disposed thereon. A metal layer 306 is disposed over alumina layer 304. Laser etching of metal layer 306 may produce an opening 307, or an opening 309, depending on various parameters such as length of exposure, energy, and so on. It can be seen that individual isolated regions of metal layer 306 are formed in this way.

### CONCLUSION

Various embodiments of the present invention include apparatus and methods for producing, by laser etching, isolated patterned electrically conductive regions disposed over a silicon wafer, and separated therefrom by a layer of material wherein the coefficient of thermal expansion of the layer of material and the coefficient of thermal expansion of the conductive material is less than the difference between the coefficient of thermal expansion of aluminum and the coefficient of thermal expansion of silicon dioxide.

Embodiments of the present invention find application in the production of wafer translators having a silicon substrate, an alumina layer disposed over the silicon and a conductive layer, such as but not limited to aluminum, disposed over the aluminum.

An advantage of some embodiments of the present invention is that practical manufacturing yields are made possible by the reduction or elimination of electrical shorts that commonly occur with laser etching of a metal layer that is disposed over a layer of an oxide of silicon.

It is to be understood that the present invention is not limited to the embodiments described above, but encompasses any and all embodiments within the scope of the subjoined Claims and their equivalents.

What is claimed is:

1. A method of forming a structure, comprising:
providing a substrate having a first major surface and a second major surface;
forming a first layer on the first major surface;
forming a first conductive layer on the first layer; and
removing portions of the first conductive layer so as to form at least one electrically isolated conductive structure;
wherein the difference between the coefficient of thermal expansion of the first layer and the coefficient of thermal expansion of the first conductive layer, is less than the difference between the coefficient of thermal expansion of aluminum and the coefficient of thermal expansion of the silicon dioxide.

2. The method of claim 1, wherein the substrate comprises a silicon wafer, the first layer comprises alumina, and the first conductive layer comprises aluminum.

3. The method of claim 2, wherein removing portions of the first conductive layer comprises exposing those portions to a laser beam.

4. The method of claim 2, further comprising removing portions of the alumina;
wherein removing portions of the aluminum and alumina comprises exposing those portions to a laser beam.

5. The method of claim 2, further comprising removing portions of the alumina and silicon;
wherein removing portions of the aluminum, alumina, and silicon comprises exposing those portions to a laser beam.

6. A method of forming a structure, comprising:
providing a substrate having a first major surface and a second major surface;
forming a first layer on the first major surface;
forming a first conductive layer on the first layer; and
removing portions of the first conductive layer so as to form at least one electrically isolated conductive structure;
wherein the difference between the thermal conductivity of the first layer and the thermal conductivity of the first conductive layer is less than the difference between the thermal conductivity of aluminum and the thermal conductivity of silicon dioxide.

7. The method of claim 6, wherein the substrate comprises silicon, the first layer comprises alumina, and the first conductive layer comprises aluminum.

8. The method of claim 7, wherein removing portions of the first conductive layer comprises exposing those portions to a laser beam.

9. The method of claim 7, further comprising removing portions of the alumina;
wherein removing portions of the aluminum and alumina comprises exposing those portions to a laser beam.

10. The method of claim 7, further comprising removing portions of the alumina and silicon;
wherein removing portions of the aluminum, alumina, and silicon wafer comprises exposing those portions to a laser beam.

11. A method of manufacturing a wafer translator, comprising:
providing a substrate comprising silicon, the substrate having an first layer disposed on the silicon, and a conductive layer disposed on the alumina; and
removing portions of the conductive layer to form a plurality of electrically isolated portions of conductive material;
wherein removing portions of the aluminum layer comprises exposing those portions to a laser beam; and wherein the difference between the thermal conductivity of the first layer and the thermal conductivity of the first conductive layer is less than the difference between the thermal conductivity of aluminum and the thermal conductivity of silicon dioxide.

12. The method of claim 11, wherein the first layer comprises alumina, the conductive layer comprises aluminum; and further comprising removing portions of the alumina layer with the laser beam.
